(19) United States
(12) Patent Application Publication
(10) Pub. No.: US 2008/0185695 A1
(43) Pub. Date: Aug. 7, 2008

(54) PACKAGE-ON-PACKAGE DEVICE AND METHOD FOR MANUFACTURING THE SAME BY USING A LEADFRAME

(76) Inventors: Hong Hyoun KIM, Paju-Si (KR); Minglu Cui, Paju-Si (KR)

Correspondence Address: LOWE HAUPTMAN HAM & BERNER, LLP, 1700 DIAGONAL ROAD, SUITE 300, ALEXANDRIA, VA, 22314, US

(21) Appl. No.: 11/672,511

(22) Filed: Feb. 7, 2007

(51) Int. Cl. H01L 23/495

(52) U.S. Cl. 257/670; 257/666; 257/E23.032

(57) ABSTRACT

A POP device includes a leadframe, a first chip, an encapsulant and a second chip. The leadframe includes a die pad, a plurality of first and second leads. First leads have first top and bottom surfaces. Second leads include top leads, bottom leads and intermediate leads physically connected to top leads and bottom leads. Top leads have second top surfaces. Bottom leads have second bottom surfaces. The top lead and the bottom lead are not coplanar, and the bottom lead and the first lead are coplanar. The first chip is mounted on the die pad and electrically connected to the first top surfaces. The encapsulant seals the first chip and a part of the leadframe, and exposes the first bottom surfaces, the second top surfaces and the second bottom surfaces. The second chip is mounted on the encapsulant and electrically connected to the second top surfaces.

### BACKGROUND OF THE INVENTION

1. Field of the Invention

The present invention generally relates to a package-on-package device, and more particularly to a package-on-package device including a single leadframe having first and second leads for electrically connecting to the chips of the top and bottom packages respectively.

2. Description of the Related Art

Currently, a package-on-package (hereinafter referred to as “POP”) device is related to a semiconductor package disposed on another semiconductor package. The basic object of the POP device is to increase the density of components so as to result in more functions of components per unit volume and better regional efficiency. Thus, the total area of the POP device can be decreased, and the cost is reduced simultaneously.

FIG. 1 is a diagrammatic sketch in a sectional view illustrating the structure of an example of a conventional package-on-package (POP) device 20, i.e. a two-stack multi-package module (MPM), in which the interconnection is made by solder balls 28. In this POP device, a first package is the “bottom” package, and a second package is the “top” package. The top package is stacked on the bottom package, and the solder balls 28 on the top package are arranged at the periphery of a substrate 22 of the top package, so that the solder balls 28 function as the interconnection without interference with the encapsulation of the bottom package. The top package includes a chip 24 attached onto the substrate 22. The substrate 22 of the top package has upper and lower metal layers patterned to provide appropriate circuitry and connected by way of vias. The chip 24 is attached to an upper surface of the substrate 22 by using an adhesive 23, e.g. die attach epoxy. The bottom package includes a chip 14 attached onto a substrate 12. The substrate 12 of the bottom package also has upper and lower metal layers patterned to provide appropriate circuitry and connected by way of vias. The chip 14 is attached to an upper surface of the substrate 12 by using an adhesive 13, e.g. die attach epoxy.

In the top and bottom packages, the chips 24, 14 are respectively bonded to wire bond sites on the upper metal layer of the substrate 22, 12 by means of bonding wires 26, 16, so as to establish electrical connections. The chips 24, 14 and the bonding wires 26, 16 are respectively encapsulated with top and bottom molding compound 27, 17. Solder balls 28 are reflowed onto bonding pads located on the peripheral margin of the lower metal layer of the substrate 22 to provide interconnection to the bottom package. Solder balls 18 are reflowed onto bonding pads located on the lower metal layer of the substrate 12 to provide electrical connection to an external circuit board (not shown).

The interconnection in POP device 20 of FIG. 1 is achieved by reflowing the solder balls 28 attached to peripheral bonding pads on the lower metal layer of the substrate 22 of the top package and attached to peripheral bonding pads on the upper metal layer of the substrate 12 of the bottom package. This type of interconnection requires that the upper and lower substrates 22, 12 be designed to match with the bonding pads for the solder balls 28. If one of the packages is changed to one of which the substrate has a different bonding pad arrangement (different size or different design), then the substrate for the other package must be reconfigured accordingly. This leads to increase the cost for manufacturing of the POP device. In this configuration the distance h between the top and bottom packages must be at least as great as the encapsulation height of the bottom package. The solder balls 28 must have a sufficient large diameter such that when they are reflowed they make good contact with the bonding pads of the bottom package; that is, the diameter of the solder ball 28 must be greater than the height of encapsulation. A larger ball diameter dictates a larger ball pitch that in turn limits the number of balls that can be fitted in the available space.

U.S. Pat. No. 7,101,731, entitled “Semiconductor multi-package module having inverted second package stacked over die-up flip-chip ball grid array (BGA) package” discloses a semiconductor multi-package module including stacked lower and upper packages (first and second packages), each of which includes a die attached to a substrate, in which the second package is inverted, and in which the first and second substrates are interconnected by wire bonding, and in which the first package includes a flip-chip ball grid array package having a flip-chip in a die-down configuration.

However, the prior art fails to disclose a package-on-package device including a single leadframe having first and second leads for electrically connected to the chips of the top and bottom packages respectively, wherein the manufacture cost can be reduced by using the single leadframe.

Accordingly, there exists a need for a package-on-package device capable of solving the above-mentioned problems.

### SUMMARY OF THE INVENTION

It is an object of the present invention to provide a package-on-package device including a single leadframe having first and second leads for electrically connecting to the chips of the top and bottom packages respectively.

In order to achieve the foregoing object, the present invention provides a package-on-package (POP) device including a leadframe, a first chip, an encapsulant and a second chip. The leadframe includes a die pad, a plurality of first and second leads. First leads have first top and bottom surfaces. Second leads include top leads, bottom leads and intermediate leads physically connected to top leads and bottom leads. Top leads have second top surfaces. Bottom leads have second bottom surfaces. The top lead and the bottom lead are not coplanar, and the bottom lead and the first lead are coplanar. The first chip is mounted on the die pad and electrically connected to the first top surfaces. The encapsulant seals the first chip and a part of the leadframe, and exposes the first bottom surfaces, the second top surfaces and the second bottom surfaces. The second chip is mounted on the encapsulant and electrically connected to the second top surfaces.

The POP device of the present invention does not require upper and lower substrates, and thus the present invention can reduce the manufacture cost, because the upper and lower substrates in the prior art are replaced with a single leadframe. Furthermore, the POP device of the present invention includes a single leadframe having first and second leads for electrically connecting to the chips of the top and bottom packages respectively. Compared with the prior art, the top package of the POP device of the present invention is only constituted by the second chip, the second bonding wires and the second encapsulant and thus the cost of the mounting processes of the top package can be reduced.

The foregoing, as well as additional objects, features and advantages of the invention will be more apparent from the following detailed description, which proceeds with reference to the accompanying drawings.

### BRIEF DESCRIPTION OF THE DRAWINGS

FIG. 1 is a cross-sectional schematic view of a package-on-package device in the prior art.

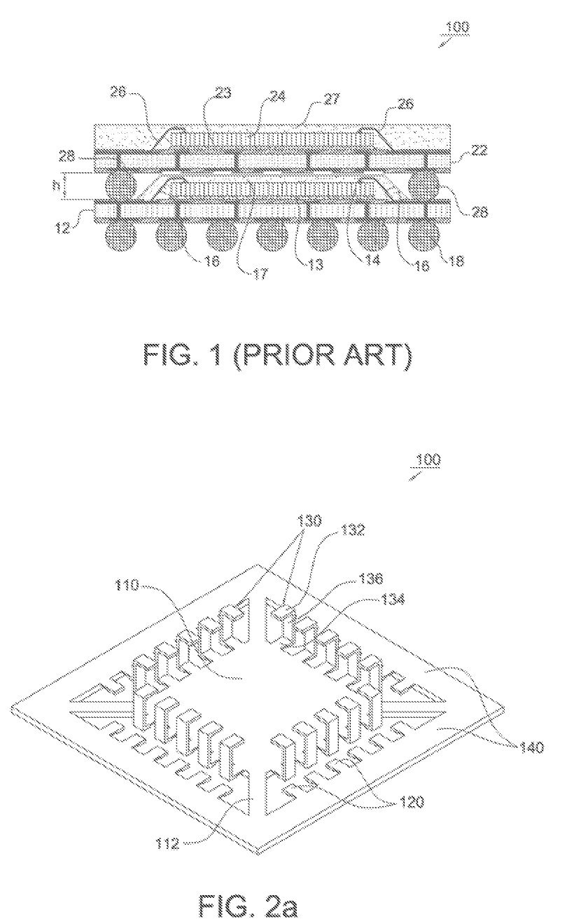

FIG. 2a is a front-right-top perspective schematic view of a leadframe according to an embodiment of the present invention.

FIG. 2b is a front-right-bottom perspective schematic view of a leadframe according to an alternative embodiment of the present invention.

FIG. 3a is a perspective schematic view of a package-on-package device according to the first embodiment of the present invention.

FIGS. 3b and 3c are cross-sectional schematic views of the package-on-package device along line 3b-3b and line 3c-3c of FIG. 3a.

FIGS. 4a to 4d are perspective schematic views of a method for manufacturing a package-on-package device according to the first embodiment of the present invention.

FIG. 5 is a perspective schematic view of a package-on-package device according to the second embodiment of the present invention.

FIG. 6 is a perspective schematic view of a package-on-package device according to the third embodiment of the present invention.

### DETAILED DESCRIPTION OF THE PREFERRED EMBODIMENT

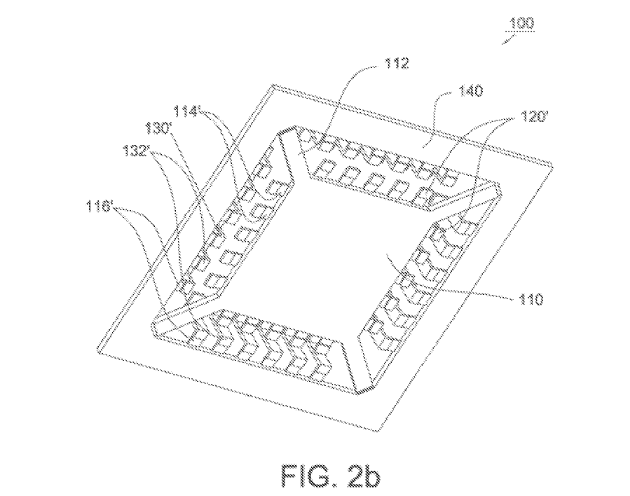

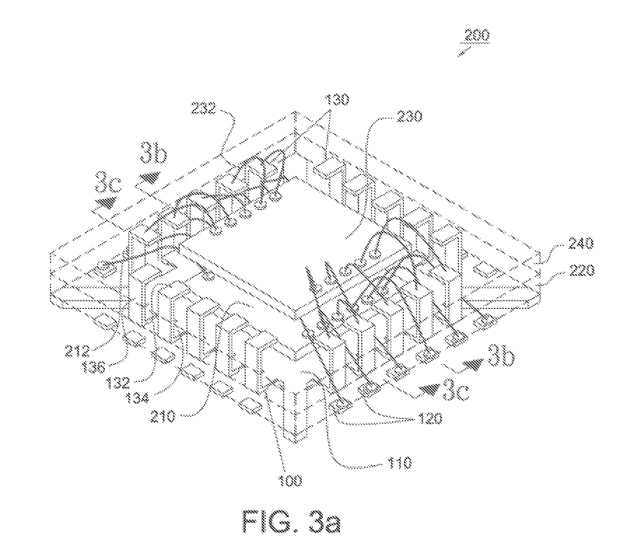

Referring to FIG. 2a, it depicts a leadframe 100 according to an embodiment of the present invention. The leadframe 100 includes a die pad 110, a plurality of first leads 120, a plurality of second leads 130, a dam bar 140 and a plurality of tie bars 112. Each second lead 130 includes a top lead 132, a bottom lead 134 and an intermediate lead 136. The intermediate lead 136 is physically connected to the top lead 132 and the bottom lead 134. The top lead 132 and the bottom lead 134 are non-coplanar, and the bottom lead 134 and the first lead 120 are coplanar. The dam bar 140 is disposed about the periphery of the die pad 110 and spaced from the die pad 110. The tie bars 112 are used for connecting the die pad 110 to the dam bar 140.

In this embodiment, the first leads 120 are physically connected to the dam bar 140, and the second leads 130 are physically connected to the die pad 110, shown in FIG. 2a. Thus, the dam bar 140 can support the die pad 110, the first leads 120 and the second leads 130. Each first lead 120 has a half-etching region (not shown) adjacent to the dam bar 140, and each second lead 130 has a half-etching region (not shown) adjacent to the die pad 110.

In another embodiment, the first leads 120′ are physically connected to the die pad 110, and the second leads 130′ are physically connected to the dam bar 140, shown in FIG. 2b. Thus, the dam bar 140 can support the die pad 110, the first leads 120′ and the second leads 130′. Each first lead 120′ has a half-etching region 114′ adjacent to the die pad 110, and each second lead 130′ has a half-etching region 116′ adjacent to the dam bar 140, shown in FIG. 2b. Furthermore, the second leads 130′ can be similarly Z-shaped leads, shown in FIG. 2b.

Likewise, in a further embodiment, both the first and second leads (not shown) can be physically connected to the dam bar, wherein all first and second leads have half-etching regions adjacent to the dam bar. In a still further embodiment, both the first and second leads (not shown) can be physically connected to the die pad, wherein all first and second leads have half-etching regions adjacent to the die pad.

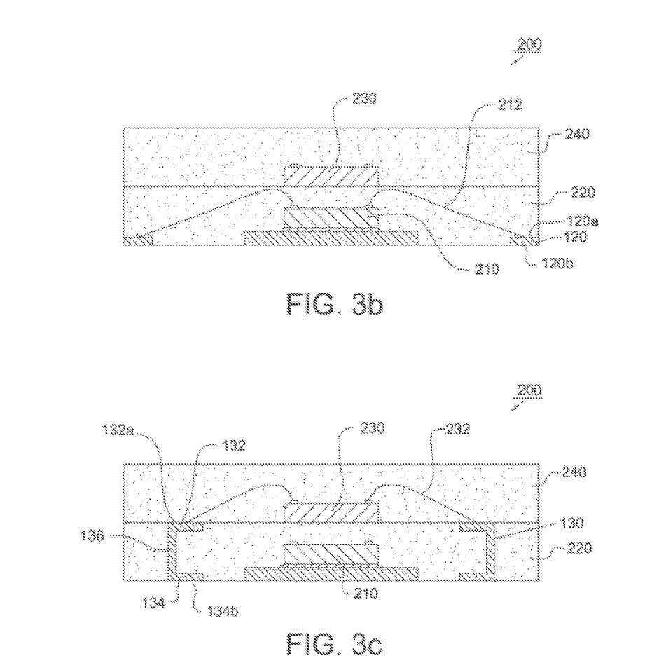

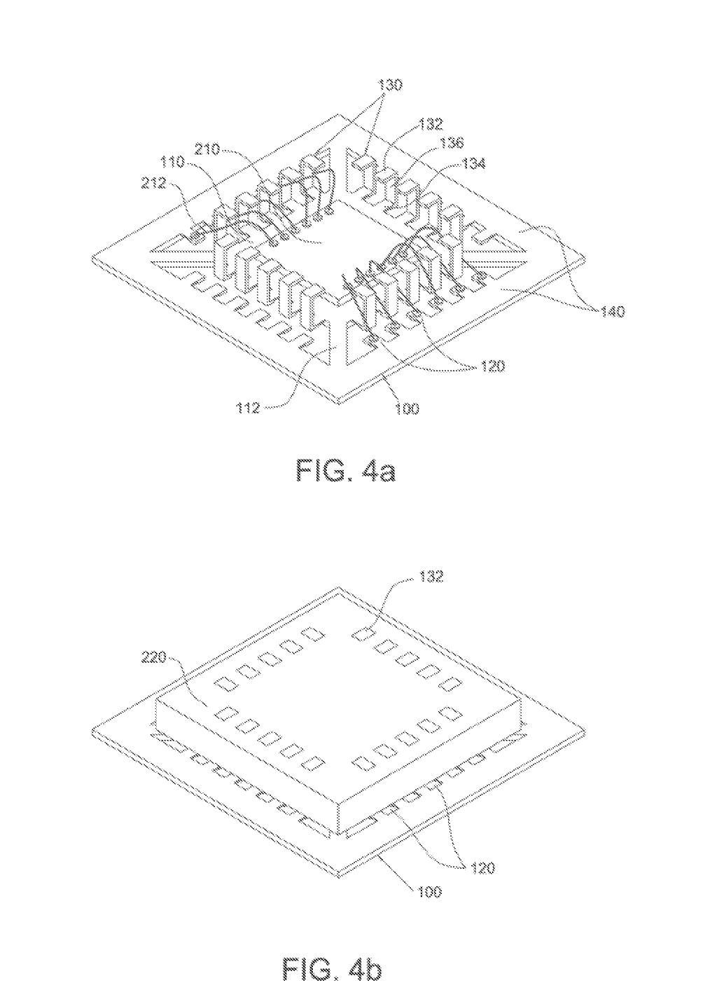

Referring to FIGS. 3a to 3c, they depict a package-on-package (hereinafter referred to as “POP”) device 200 according to the first embodiment of the present invention. The POP device 200 includes a leadframe 100, a first chip 210, a first encapsulant 220 and a second chip 230.

The leadframe 100 includes a die pad 110, a plurality of first leads 120 and a plurality of second leads 130. The first leads 120 and the second leads 130 are electrically isolated from each other. Each first lead 120 has a top surface 120a and a bottom surface 120b. Each second lead 130 includes a top lead 132, a bottom lead 134 and an intermediate lead 136 physically connected to the top lead 132 and the bottom lead 134, wherein each top lead 132 has a top surface 132a, and each bottom lead 134 has a bottom surface 134b. The top lead 132 and the bottom lead 134 are non-coplanar, and the bottom lead 134 and the first lead 120 are coplanar.

The first chip 210 is mounted on the die pad 110, and is electrically connected to the top surfaces 120a of the first leads 120 by means of a plurality of first bonding wires 212, shown in FIG. 3b. The first encapsulant 220 seals the first chip 210, a part of the leadframe 100 and the first bonding wires 212, and exposes the bottom surfaces 120b of the first leads 120, and the top surfaces 130a of the top leads 132 and the bottom surfaces 130b of the bottom leads 134. The second chip 230 is mounted on the first encapsulant 220, and is electrically connected to the top surfaces 132a of the top leads 132 of the second leads 130 by means of a plurality of second bonding wires 232, i.e. using a wire bonding technology, shown in FIG. 3c.

The POP device 200 further includes a second encapsulant 240, which seals the second chip 230, the second bonding wires 232 and the top surfaces 132a of the top leads 132 of the second leads 130. Since the first and second encapsulants 220, 240 do not seal the bottom surfaces 120b of the first leads 120 and the bottom surfaces 134b of the bottom lead 134 of the second leads 130, the bottom surfaces 120b of the first leads 120 and the bottom surfaces 134b of the bottom lead 134 of the second leads 130 can be acted as electrical contacts.

As described above, the POP device of the present invention does not require upper and lower substrates, and thus the present invention can reduce the manufacture cost because the upper and lower substrates in the prior art are replaced with a single leadframe.

Furthermore, the top package of the POP device of the present invention is constituted by the second chip 230, the second bonding wires 232 and the second encapsulant 240, and the bottom package of the POP device is constituted by the first chip 210, the first bonding wires 212, the first encapsulant 220 and the leadframe 100. The POP device of the present invention includes a single leadframe having first and second leads for electrically connecting to the chips of the top and bottom packages respectively.

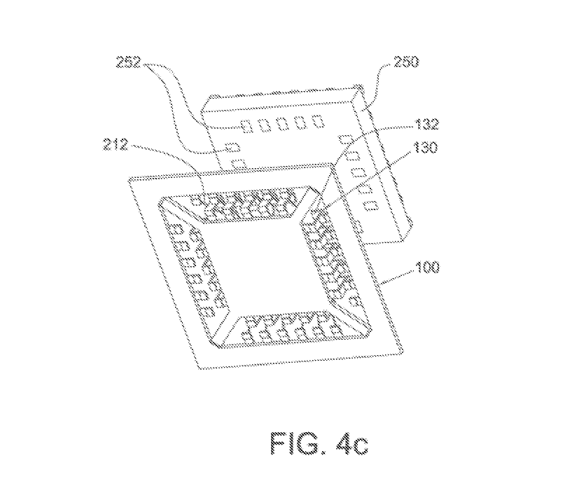

FIGS. 4a to 4d show a method for manufacturing a package-on-package (POP) device according to the first embodiment of the present invention. Referring to FIG. 4a, a leadframe 100 is provided. The leadframe 100 includes a die pad 110, a plurality of first leads 120, a plurality of second leads 130, a dam bar 140 and a plurality of tie bars 112, wherein each first lead 120 has a top surface and a bottom surface, each second lead 130 includes a top lead 132, a bottom lead 134 and an intermediate lead 136 physically connected to the top lead 132 and the bottom lead 134, each top lead 132 has a top surface, each bottom lead 134 has a bottom surface, the top lead 132 and the bottom lead 134 are non-coplanar, the bottom lead 134 and the first lead 120 are coplanar, the dam bar 140 is disposed about the periphery of the die pad 110 and spaced from the die pad 110, and the tie bars 112 are used for connecting the die pad 110 to the dam bar 140. A first chip 210 is mounted on the die pad 110 by means of an adhesive, and is electrically connected to the top surfaces of the first leads 120 by means of a plurality of first bonding wires 212.

Referring to FIG. 4b, the first chip 210, a part of the leadframe 100 and the first bonding wires 212 are sealed by molding a first encapsulant 220, wherein the first encapsulant 220 exposes the bottom surfaces of the first leads 120, the top surfaces of the top leads 132 and the bottom surfaces of the bottom leads 134. In particular, a mold chase 250 can be put on the top leads 132 of the second leads 130 when the first chip 210, a part of the leadframe 100 and the first bonding wires 212 are sealed, shown in FIG. 4c. The mold chase 250 includes a plurality of buffers 252, which contact the top surfaces of the top leads 132 of the second leads 130. The buffer 252 can be made of elastomer material or lubricant material.

Referring to FIG. 4d, a second chip 230 is mounted on the first encapsulant 220 by means of an adhesive, and is electrically connected to the top surfaces of the top leads 132 of the second leads 130 by means of a plurality of second bonding wires 232.

The second chip 230, the top surfaces of the top leads 132 of the second leads 130 and the second bonding wires 232 by molding a second encapsulant 240. Finally, half-etching regions of the bottom leads 134 of the second leads 130 are etched or sawn, and half-etching regions of the first lead 120 are etched or sawn, so as to singularize the individual POP device 200, shown in FIG. 3a.

Compared with the prior art, the top package of the POP device of the present invention is only constituted by the second chip, the second bonding wires and the second encapsulant, and thus the cost of the mounting processes of the top package can be reduced.

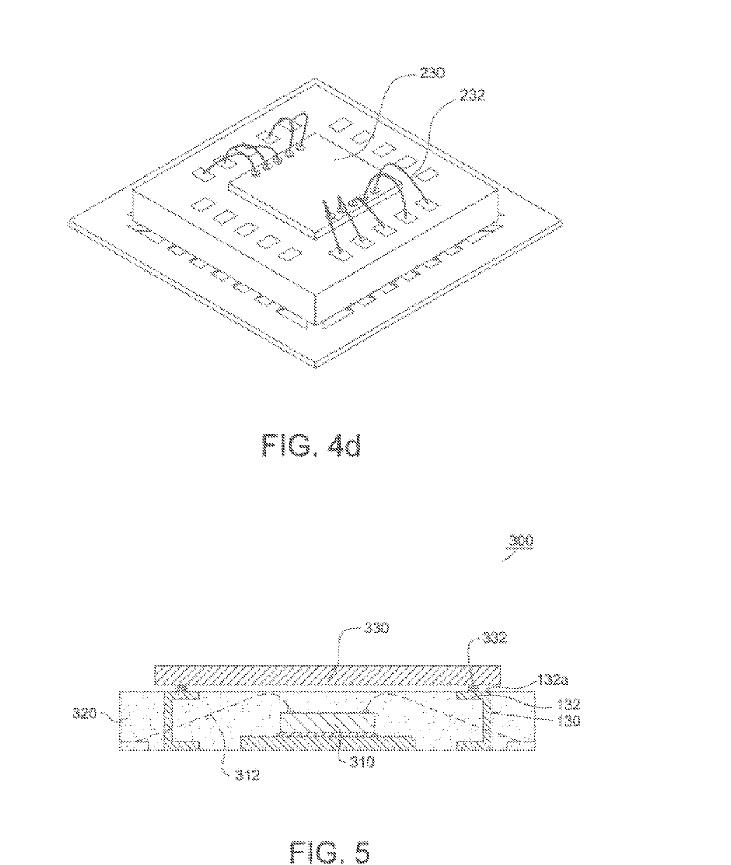

Referring to FIG. 5, it depicts a package-on-package (POP) device 300 according to the second embodiment of the present invention. The lower package of the POP device 300 is similar to the lower package of the POP device 200 in the first embodiment, wherein the similar elements are designated with the similar reference numerals. Compared with the POP device 200 in the first embodiment, the POP device 300 in the second embodiment includes a plurality of bumps 332 for electrically connecting a second chip 330 to the top surfaces 132a of the top leads 132 of the second leads 130, i.e. using a flip chip bonding technology.

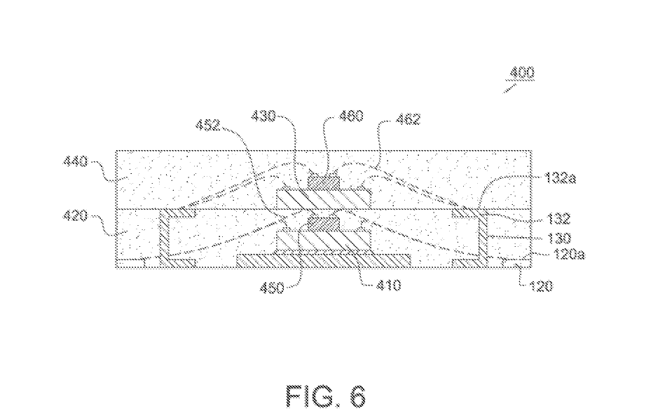

Referring to FIG. 6, it depicts a package-on-package (POP) device 400 according to the third embodiment of the present invention. The POP device 400 is similar to the POP device 200 in the first embodiment, wherein the similar elements are designated with the similar reference numerals. Compared with the POP device 200 in the first embodiment, the POP device 400 in the third embodiment further includes a third chip 450 and a fourth chip 460, which can be stacked on the first chip 410 and the second chip 430 respectively. The third chip 450 is electrically connected to the top surfaces 120a of the first leads 120 by means of a plurality of third bonding wires 452. The fourth chip 460 is electrically connected to the top surfaces 132a of the top leads 132 of the second leads 130 by means of a plurality of fourth bonding wires 462. In an alternative embodiment, the third chip (not shown) and the first chip 410 can be mounted on the die pad 110 in parallel, and the third chip is electrically connected to the top surfaces 120a of the first leads 120. Likewise, the fourth chip (not shown) and the second chip 430 can be mounted on the first encapsulant 420 in parallel, and the fourth chip is electrically connected to the top surfaces 132a of the top leads 132 of the second leads 130.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A package-on-package device comprising:
a leadframe comprising:
a die pad;
a plurality of first leads, each having a first top surface and a first bottom surface; and
a plurality of second leads, each including a top lead, a bottom lead and an intermediate lead physically connected to the top lead and the bottom lead, wherein each top lead has a second top surface, each bottom lead has a second bottom surface, the top lead and the bottom lead are non-coplanar, and the bottom lead and the first lead are coplanar; and
a first chip mounted on the die pad and electrically connected to the first top surfaces of the first leads;
a first encapsulant adapted to seal the first chip and a part of the leadframe, and adapted to expose the first bottom surfaces, the second top surfaces and the second bottom surfaces; and
a second chip mounted on the first encapsulant and electrically connected to the second top surfaces of the top leads of the second leads.

2. The package-on-package device as claimed in claim 1, further comprising:
a plurality of first bonding wires adapted for electrically connecting the first chip to the first top surfaces of the first leads.

3. The package-on-package device as claimed in claim 1, further comprising:
a plurality of second bonding wires adapted for electrically connecting the second chip to the second top surfaces of the top leads of the second leads.

4. The package-on-package device as claimed in claim 3, further comprising:
a second encapsulant adapted to seal the second chip, the second bonding wires and the second top surfaces of the top leads of the second leads.

5. The package-on-package device as claimed in claim 1, further comprising:
a plurality of bumps adapted for electrically connecting the second chip to the second top surfaces of the top leads of the second leads.

6. The package-on-package device as claimed in claim 1, further comprising:
a third chip stacked on the first chip and electrically connected to the first top surfaces of the first leads.

7. The package-on-package device as claimed in claim 1, further comprising:
a fourth chip stacked on the second chip and electrically connected to the second top surfaces of the top leads of the second leads.

8. The package-on-package device as claimed in claim 1, wherein the first leads and the second leads are electrically isolated from each other.

9. The package-on-package device as claimed in claim 1, wherein the first bottom surfaces of the first leads are electrical contacts.

10. The package-on-package device as claimed in claim 1, wherein the second bottom surfaces of the bottom lead of the second leads are electrical contacts.

11. A leadframe comprising:
a die pad;
a plurality of first leads;
a plurality of second leads, each including a top lead, a bottom lead and an intermediate lead physically connected to the top lead and the bottom lead, wherein the top lead and the bottom lead are non-coplanar, and the bottom lead and the first lead are coplanar;
a dam bar disposed about the periphery of the die pad and spaced therefrom; and
a plurality of tie bars for connecting the die pad to the dam bar.

12. The leadframe as claimed in claim 11, wherein the first leads are physically connected to the dam bar, and the second leads are physically connected to the die pad.

13. The leadframe as claimed in claim 12, wherein each first lead has a half-etching region adjacent to the dam bar, and each second lead has a half-etching region adjacent to the die pad.

14. The leadframe as claimed in claim 11, wherein the first leads are physically connected to the die pad, and the second leads are physically connected to the dam bar.

15. The leadframe as claimed in claim 14, wherein each first lead has a half-etching region adjacent to the die pad, and each second lead has a half-etching region adjacent to the dam bar.

16. The leadframe as claimed in claim 11, wherein the first and second leads are physically connected to the dam bar.

17. The leadframe as claimed in claim 16, wherein all first and second leads have sawing half-etching regions adjacent to the dam bar.

18. The leadframe as claimed in claim 11, wherein the first and second leads are physically connected to the die pad.

19. The leadframe as claimed in claim 18, wherein all first and second leads have half-etching regions adjacent to the die pad.

20. The leadframe as claimed in claim 11, wherein the second leads are similarly Z-shaped leads.
